(19) United States
(12) Patent Application Publication
(10) Pub. No.: US 2026/0239720 A1
(43) Pub. Date: Aug. 13, 2026

(54) Method for manufacturing semiconductor device

(71) Applicant: Shanghai Huali Integrated Circuit Corporation, Shanghai (CN)

(72) Inventors: Qiwei WANG, Shanghai (CN); Shiyou PAN, Shanghai (CN); Wei ZHAO, Shanghai (CN)

(73) Assignee: Shanghai Huali Integrated Circuit Corporation, Shanghai (CN)

(21) Appl. No.: 19/534,812

(22) Filed: Feb. 10, 2026

(30) Foreign Application Priority Data
Feb. 12, 2025 (CN) 2025101572059

(51) Int. Cl. H10D 84/01; H10P 30/22; H10P 76/40

(52) U.S. Cl. CPC H10D 84/0156; H10P 30/22; H10P 76/4083

(57) ABSTRACT

The present disclosure provides a method for manufacturing an embedded high-voltage HKMG semiconductor device. A hard mask layer is first formed before forming a well region of a first-conductivity-type doped device and a well region of a second-conductivity-type doped device, an opening in the hard mask layer is formed in the steps of forming the well region of the first-conductivity-type doped device and the well region of the second-conductivity-type doped device, and then the hard mask layer serves as a barrier layer to etch the medium-voltage device region, eliminating the need for defining an active area recess etching in the medium-voltage device region, thereby reducing the number of photomasks and lowering costs.

### FIELD OF TECHNOLOGY

The present disclosure belongs to the technical field of semiconductors and in particular, it relates to a manufacturing method for semiconductor devices.

### BACKGROUND

High-k Metal Gate (HKMG) process is an advanced semiconductor fabrication technology, which has enabled substantial improvements in performance and reliability of integrated circuits.

As shown in FIG. 1, which displays a schematic diagram of an embedded high-voltage HKMG device including a low-voltage region 010, a medium-voltage region 011, and a high-voltage region 012, the high-voltage region 012 and the medium-voltage region 011 utilize a thicker gate dielectric layer 013 compared to the low-voltage region 010. To improve process compatibility, the medium-voltage region 011 and the high-voltage region 012 need to undergo active area recess etching to achieve metal gate height balance among the high-voltage region 012, medium-voltage region 011, and low-voltage region 010 during the Metal Gate Chemical Mechanical Polishing (MG CMP) process. In the related art, the high- voltage gate dielectric layer and the medium-voltage gate dielectric layer of an embedded high-voltage HKMG device need to be defined in position using photomask (mask) before subjected to an etch-back process. This results in a large number of mask layers in the process which induces high costs, thus unfavorable for enhancing the competitiveness of the device.

Therefore, to provide a method for manufacturing a semiconductor device that reduces the number of mask layers and lowers costs for embedded high- voltage HKMG devices has become an urgent technical problem for those in the field.

### SUMMARY

The present disclosure provides a method for manufacturing a semiconductor device, thus reducing the large number of mask layers and high cost in making embedded high-voltage HKMG device.

The method includes:

S1: providing a semiconductor substrate, forming a sacrificial layer on an upper surface of the semiconductor substrate, wherein the semiconductor substrate is divided into a first voltage device region, a second voltage device region, and a third voltage device region, wherein the second voltage device region comprises a first-conductivity-type doped device region and a second- conductivity-type doped device region;

S2: forming a hard mask layer on the sacrificial layer, forming a first photoresist layer on the hard mask layer, patterning the first photoresist layer using a first photomask to form a first opening, wherein the first opening exposes the hard mask layer above the first-conductivity-type doped device region;

S3: etching the hard mask layer based on the patterned first photoresist layer to form a second opening, and performing ion implantation on the first- conductivity-type doped device region based on the second opening to form a well region for the first-conductivity-type doped device region;

S4: forming a second photoresist layer on the hard mask layer, patterning the second photoresist layer using a second photomask to form a third opening, wherein the third opening exposes the hard mask layer above the second- conductivity-type doped device region;

S5: etching the hard mask layer based on the patterned second photoresist layer to form a fourth opening, and performing ion implantation on the second- conductivity-type doped device region based on the fourth opening to form a well region of the second-conductivity-type doped device region;

S6: etching to remove the second photoresist layer and the sacrificial layer above the second voltage device region using the hard mask layer that has formed the second opening and the second and fourth opening openings as a mask, etching to remove the sacrificial layer above the second voltage device region, and further etching the second voltage device region to a predetermined depth to form a trench in the second voltage device region; and

S7: forming a gate dielectric layer for the second voltage device region in the trench of the second voltage device region. Optionally, a material of the sacrificial layer is silicon oxide, and a material of the hard mask layer is silicon nitride.

Optionally, the sacrificial layer is used as an etching stop layer in a process of etching the hard mask layer to form the second opening; the sacrificial layer is used as an etching stop layer in a process of etching the hard mask layer to form the fourth opening.

Optionally, in step S6, the sacrificial layer above the second voltage device region is removed by a wet etching method.

Optionally, an etchant of the wet etching method includes an HF solution.

Optionally, the method for manufacturing a semiconductor device further includes: forming a gate dielectric layer for the third voltage device region in the third voltage device region before forming the hard mask layer

Optionally, a thickness of the gate dielectric layer for the second voltage device region is less than a thickness of the gate dielectric layer for the third voltage device region.

Optionally, the first-conductivity-type doped device region is an N-type device region, and the second-conductivity-type doped device region is a P-type device region; or the first-conductivity-type doped device region is a P-type device region and the second-conductivity-type doped device region is an N-type device region.

Optionally, in step S6, after forming the trench in the second voltage device region, the hard mask layer with a predetermined depth remains on the semiconductor substrate; in step S7, first removing the remaining hard mask layer, and then forming the gate dielectric layer for the second voltage device region.

Optionally, the remaining hard mask layer is removed by a wet etching method.

As described above, in the method for manufacturing a semiconductor device described in the present disclosure, a hard mask layer is formed before forming the well region of the first-conductivity-type doped device region and the well region of the second-conductivity-type doped device region, an opening of the hard mask layer is formed in the step of forming the well region of the first- conductivity-type doped device region and the well region of the second- conductivity-type doped device region, and then the hard mask layer serves as a barrier layer to etch the medium-voltage device region, eliminating the need for defining an active area recess etching in the medium-voltage device region, thereby reducing the number of mask layers required and lowering costs.

### BRIEF DESCRIPTION OF THE DRAWINGS

FIG. 1 shows a schematic diagram of an embedded high-voltage HKMG device.

FIG. 2 shows a schematic diagram of a structure, after a gate dielectric layer for the high-voltage region is formed on the substrate, ion implantation is performed into in a N-type device well region of the high-voltage region while the first photomask from a patterning process is used to protect the medium-voltage region.

FIG. 3 shows a schematic diagram of a structure when performing ion implantation into in a P-type device well region in the medium-voltage region while using the second photomask from a patterning process to protect the high-voltage region.

FIG. 4 shows a schematic diagram of a structure after patterning a position of the gate dielectric layer for the medium-voltage region in the P-type device well region by using the third photomask from the patterning process to protect the high-voltage region.

FIG. 5 shows a schematic diagram of performing an etch-back process on the gate dielectric layer in the active region of for the medium voltage device region.

FIG. 6 is a flowchart of a method for manufacturing a semiconductor device according to an embodiment of the present disclosure.

FIG. 7 shows a schematic diagram of providing a semiconductor substrate in an embodiment of the present disclosure.

FIG. 8 shows a schematic diagram of forming a hard mask layer and a first photoresist layer on a sacrificial layer and patterning the first photoresist layer according to an embodiment of the present disclosure.

FIG. 9 shows a schematic diagram of a structure after etching a hard mask layer and performing ion implantation for a first-conductivity-type doped device region well according to an embodiment of the present disclosure.

FIG. 10 shows a schematic diagram of a structure after forming a second photoresist layer and patterning the second photoresist layer according to an embodiment of the present disclosure.

FIG. 11 shows a schematic diagram of a structure after etching the hard mask layer and performing ion implantation for a second-conductivity-type doped device region well according to an embodiment of the present disclosure.

FIG. 12 shows a schematic diagram of a structure after removing the second photoresist layer according to an embodiment of the present disclosure.

FIG. 13 is a schematic diagram of a structure after etching the second voltage device region of the semiconductor substrate to form a trench in the second voltage device region according to an embodiment of the present disclosure.

FIG. 14 shows a schematic diagram of a structure after forming a gate dielectric layer for the second voltage device region according to an embodiment of the present disclosure.

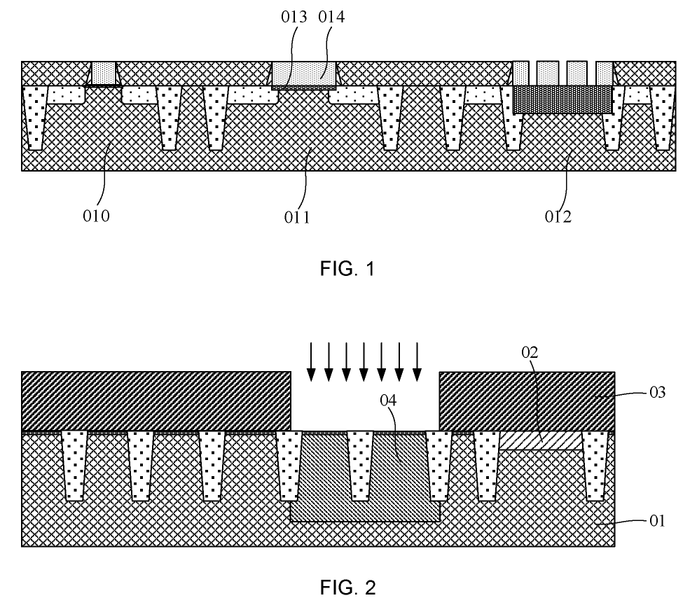

### REFERENCE NUMERALS

01 Semiconductor structure

010 Low-voltage Region

011 Medium-voltage Region

012 High-voltage region

013 Gate dielectric layer

014 Metal gate

02 Gate dielectric layer for high-voltage region

03 First photoresist layer

04 N-type device well region

05 Second photoresist layer

06 P-type device well region

07 Hard mask layer

08 Third photoresist layer

1 Semiconductor structure

100 First voltage device region

101 Second voltage device region

1010 first-conductivity-type doped device region

1011 Second-conductivity-type doped device region

1012 Well region of the first-conductivity-type doped device region

1013 Well region of the second-conductivity-type doped device region

102 Third voltage device region

1020 Gate dielectric layer for the third voltage device region

2 Sacrificial layer

3 Shallow trench isolation structure

4 Hard mask layer

5 First photoresist layer

6 First opening

7 Second opening

8 Second photoresist layer

9 Third opening

10 Fourth opening

11 Trench of the second voltage device region

12 Gate dielectric layer for the second voltage device region

S1~S7 Steps

### DETAILED DESCRIPTION

As shown in FIGS. 2 to 5, according to the related art, after forming the gate dielectric layer for the high-voltage region 02, the process operations performed on the medium-voltage region include:

(1) as shown in FIG. 2, forming a first photoresist layer 03 on the semiconductor substrate 01, and patterning the first photoresist layer 03 using a first photomask, thereby to define the position of the N-type device well region 04 in the medium-voltage region and perform ion implantation;

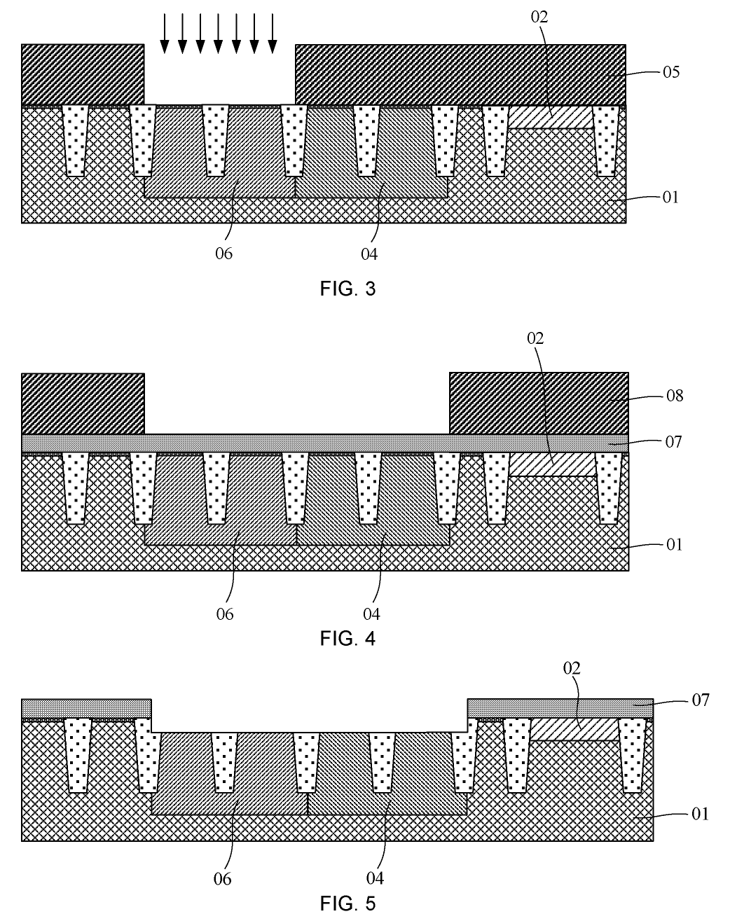

(2) as shown in FIG. 3, forming a second photoresist layer 05 on the semiconductor substrate 01, patterning the second photoresist layer 05 using a second photomask, thereby to define the position of the P-type device well region 06 in the medium-voltage region and perform ion implantation;

(3) as shown in FIG. 4, forming a hard mask layer 07 and a third photoresist layer 08 on the semiconductor substrate 01, and patterning a third photoresist layer 08 using a third photomask, thereby to define a gate dielectric layer back etching region of the medium voltage region;

(4) as shown in FIG. 5, etching the hard mask layer 07 to form an opening, and performing etch-back on the region in the semiconductor substrate 01 where the gate dielectric layer for the medium-voltage region is to be formed.

In the related art, three sets of mask are required for the well region implantation and gate dielectric layer region etch-back in the medium-voltage region. This results in a large number of mask layers and high device manufacturing costs. The purpose of the present disclosure is to eliminate the mask for the gate dielectric layer etch-back in the medium-voltage region, thereby reducing the number of mask layers and lowering costs.

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

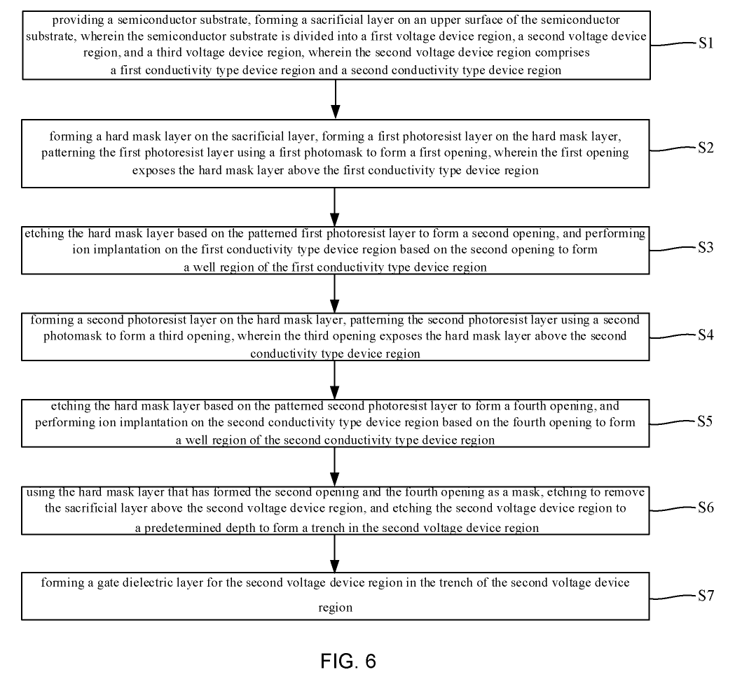

Refer to FIGS. 6-14. It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity and proportion of each component can be changed as needed, and the components' layout may also be more complicated.

The present disclosure provides a method for manufacturing a semiconductor device, refer to FIG. 6, which includes the following steps:

S1: providing a semiconductor substrate, forming a sacrificial layer on an upper surface of the semiconductor substrate, wherein the semiconductor substrate is divided into a first voltage device region, a second voltage device region, and a third voltage device region, wherein the second voltage device region comprises a first-conductivity-type doped device region and a second- conductivity-type doped device region;

S2: forming a hard mask layer on the sacrificial layer, forming a first photoresist layer on the hard mask layer, patterning the first photoresist layer using a first photomask to form a first opening, wherein the first opening exposes the hard mask layer above the first-conductivity-type doped device region;

S3: etching the hard mask layer based on the patterned first photoresist layer to form a second opening, and performing ion implantation on the first- conductivity-type doped device region based on the second opening to form a well region for the first-conductivity-type doped device region;

S4: forming a second photoresist layer on the hard mask layer, patterning the second photoresist layer using a second photomask to form a third opening, wherein the third opening exposes the hard mask layer above the second- conductivity-type doped device region;

S5: etching the hard mask layer based on the patterned second photoresist layer to form a fourth opening, and performing ion implantation on the second- conductivity-type doped device region based on the fourth opening to form a well region of the second-conductivity-type doped device region;

S6: etching to remove the second photoresist layer and the sacrificial layer above the second voltage device region using the hard mask layer that has formed the second opening and the second and fourth opening openings as a mask, etching to remove the sacrificial layer above the second voltage device region, and further etching the second voltage device region to a predetermined depth to form a trench in the second voltage device region; and

S7: forming a gate dielectric layer for the second voltage device region in the trench of the second voltage device region.

Hereinafter, the method for manufacturing the semiconductor device according to this embodiment will be described in detail with reference to specific drawings.

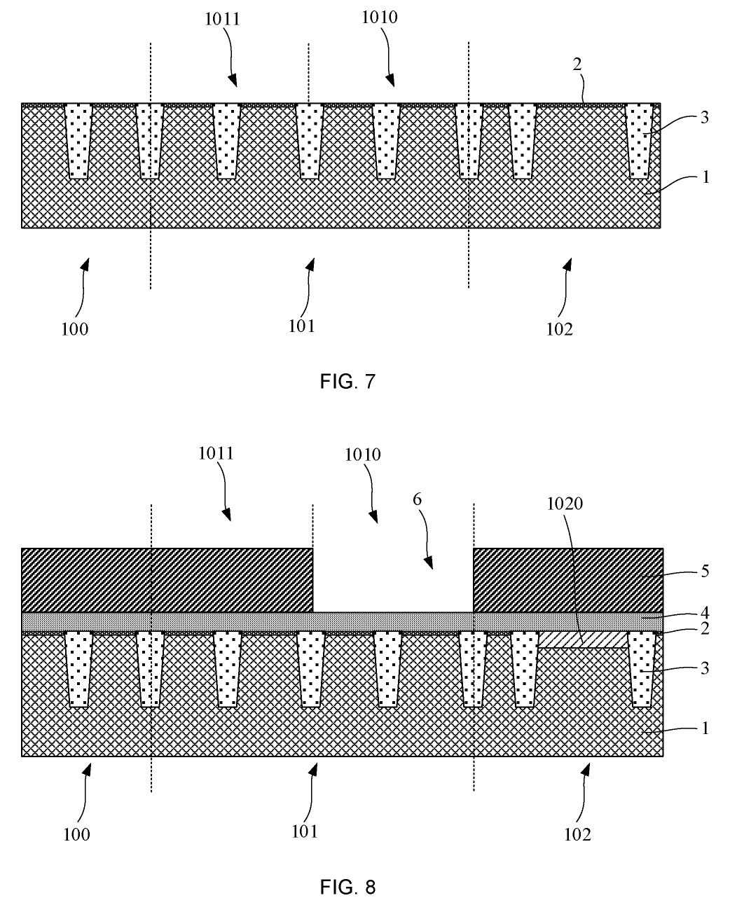

First, referring to FIG. 7, step S1 is performed: a semiconductor substrate 1 is provided, and a sacrificial layer 2 is formed on an upper surface of the semiconductor substrate 1. The semiconductor substrate 1 is divided into a first voltage device region 100, a second voltage device region 101, and a third voltage device region 102. The second voltage device region 101 includes a first- conductivity-type doped device region 1010 and a second-conductivity-type doped device region 1011.

As an example, the semiconductor substrate 1 may be any suitable semiconductor substrate, for example, a silicon (Si) substrate, a germanium (Ge) substrate, a silicon germanium (SiGe) substrate, a gallium arsenide (GaAs) substrate, a silicon carbide (SiC) substrate, a gallium nitride (GaN) substrate, a diamond substrate, or a silicon-on-insulating substrate (SOI) substrate, etc., selected according to requirements; specifically, in this embodiment, the semiconductor substrate 1 is a silicon substrate.

As an example, the sacrificial layer 2 may be a silicon oxide layer, and the sacrificial layer 2 is formed on the upper surface of the semiconductor substrate 1 by thermal oxidation or by a deposition process, selected according to requirements.

As an example, the semiconductor device in this embodiment is an embedded high-voltage HKMG device, the first voltage device region 100 is a low- voltage device region, the second voltage device region 101 is a medium-voltage device region, and the third voltage device region 102 is a high-voltage device region.

As an example, in this embodiment, the first-conductivity-type doped device region 1010 is an N-type device region, and the second-conductivity-type doped device region 1011 is a P-type device region. In another example, the first- conductivity-type doped device region 1010 is a P-type device region, and the second-conductivity-type doped device region 1011 is an N-type device region, selected according to requirements.

As an example, a shallow trench isolation structure 3 (STI) is provided in the semiconductor substrate 1 for isolating the first voltage device region 100, the second voltage device region 101, and the third voltage device region 102; in addition, the second voltage device region 101 may also be provided with the shallow trench isolation structure 3 for isolating the first-conductivity-type doped device region 1010 and the second-conductivity-type doped device region 1011; in addition, the first-conductivity-type doped device region 1010 may be provided with the shallow trench isolation structure 3 for dividing the first-conductivity-type doped device region 1010 into a plurality of functional regions, and the second- conductivity-type doped device region 1011 may be provided with the shallow trench isolation structure 3 for dividing the second-conductivity-type doped device region 1011 into a plurality of functional regions, selected according to requirements.

Next, referring to FIG. 8, step S2 is performed: a hard mask layer 4 is formed on the sacrificial layer 2, and a first photoresist layer 5 is formed on the hard mask layer 4. The first photoresist layer 5 is patterned using a first photomask to form a first opening 6, which exposes the hard mask layer 4 above the first-conductivity-type doped device region 1010.

As an example, before forming the hard mask layer 4, a step of forming a gate dielectric layer 1020 (high-voltage gate dielectric layer) for the third voltage device region 102 is further included. Specifically, the semiconductor substrate 1 located in the third voltage device region 102 is etched back to form a trench in the third voltage device region, and the gate dielectric layer 1020 for the third voltage device region is formed in the trench of the third voltage device region.

As an example, the hard mask layer 4 is formed by physical vapor deposition, chemical vapor deposition, or other suitable method, and the material of the hard mask layer 4 includes silicon nitride.

As an example, the first photoresist layer 5 is formed on the hard mask layer 4 by spin coating, spray coating, dip coating, or other suitable methods, and then the first photoresist layer 5 is patterned using processes such as exposure and development to form the first opening 6.

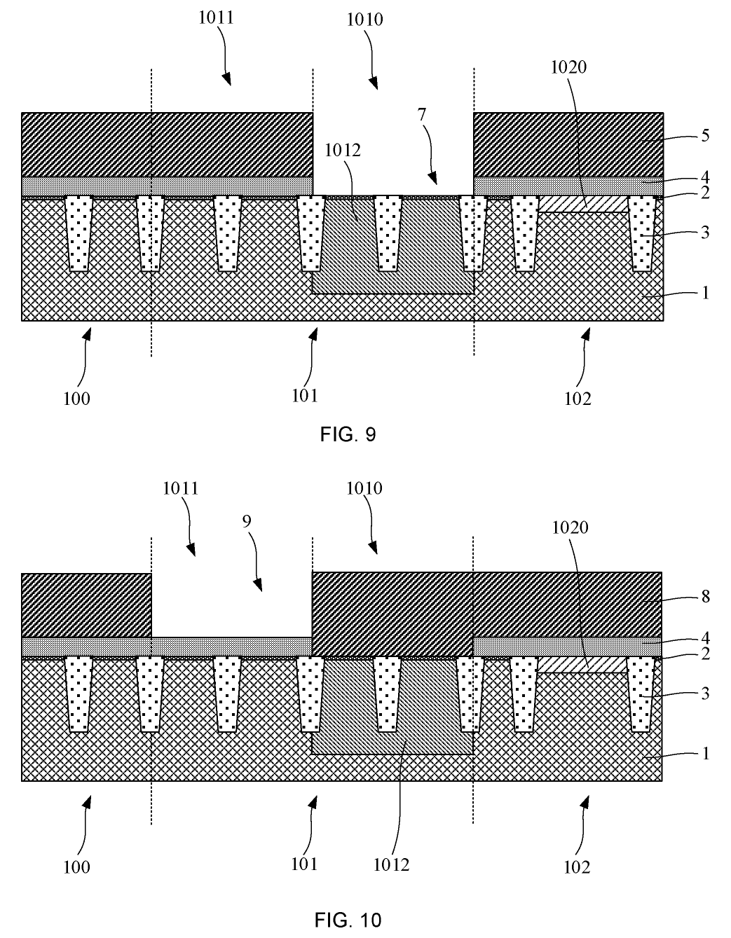

Next, referring to FIG. 9, step S3 is performed: the hard mask layer 4 is etched based on the patterned first photoresist layer 5 to form a second opening 7, and ion implantation is performed on the first-conductivity-type doped device region 1010 based on the second opening 7 to form a well region 1012 of the first- conductivity-type doped device region.

As an example, the second opening 7 is formed by etching the hard mask layer 4 using dry etching or wet etching methods, etc., and in the process of forming the second opening 7, the sacrificial layer 2 is used as an etching stop layer to avoid damaging the semiconductor substrate 1.

As an example, ion implantation is performed using the hard mask layer 4 with the formed second opening 7 as a mask to form the well region 1012 of the first-conductivity-type doped device region; in this embodiment, the first- conductivity-type doped device region 1010 is an N-type device region, and the first-conductivity-type doped device region well region 1012 is a P-well; in another example, when the first-conductivity-type doped device region 1010 is a P-type device region, the well region 1012 of the first-conductivity-type doped device region is an N-well, selected according to requirements.

As an example, after forming the well region 1012 of the first-conductivity- type doped device region, the first photoresist layer 5 is removed using ashing or other processes.

Next, referring to FIG. 10, step S4 is performed: a second photoresist layer 8 is formed on the hard mask layer 4, and the second photoresist layer 8 is patterned using a second photomask to form a third opening 9, which exposes the hard mask layer 4 above the second-conductivity-type doped device region 1011.

As an example, the second photoresist layer 8 is formed on the hard mask layer 4 by spin coating, spray coating, dip coating, or other suitable methods, and then the second photoresist layer 8 is patterned using processes such as exposure and development to form the third opening 9.

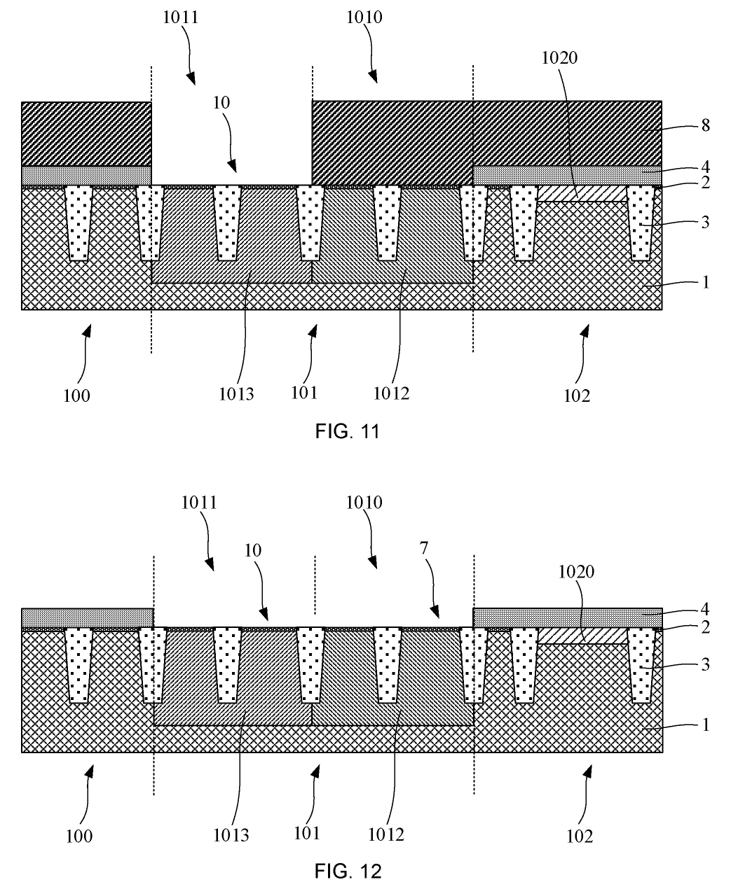

Next, referring to FIG. 11, step S5 is performed: the hard mask layer 4 is etched based on the patterned second photoresist layer 8 to form a fourth opening 10, and ion implantation is performed on the second-conductivity-type doped device region 1011 based on the fourth opening 10 to form a well region 1013 of the second-conductivity-type doped device region.

As an example, ion implantation is performed using the hard mask layer 4 with the formed fourth opening 10 as a mask to form the well region 1013 of the second-conductivity-type doped device region; in this embodiment, the second- conductivity-type doped device region 1011 is a P-type device region, and the second-conductivity-type doped device region well region 1013 is an N-well; in another example, when the second-conductivity-type doped device region 1011 is an N-type device region, the second-conductivity-type doped device region well region 1013 is a P-well, selected according to requirements.

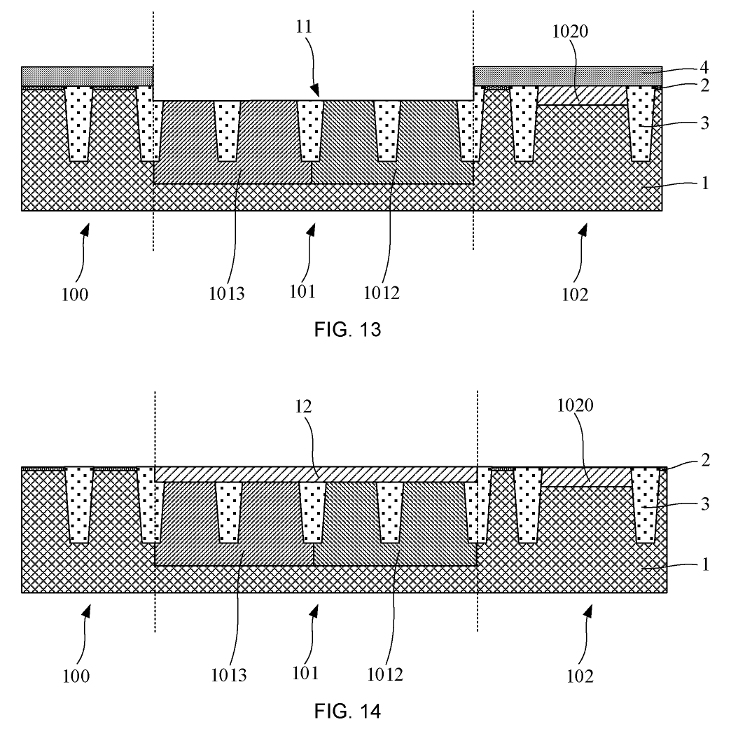

Next, referring to FIGS. 12 to 13, step S6 is performed: using the hard mask layer 4 with the formed second opening 7 and the fourth opening 10 as a mask, the sacrificial layer 2 above the second voltage device region 101 is etched and removed, and the second voltage device region 101 is etched to a predetermined depth to form a trench 11 in the second voltage device region.

As an example, as shown in FIG. 12, after forming the well region 1013 of the second-conductivity-type doped device region, the second photoresist layer 8 is removed using ashing or other processes.

As an example, a wet etching method is used to remove the sacrificial layer 2 above the second voltage device region 101, and the wet etchant includes an HF solution.

As an example, in the process of removing the sacrificial layer 2 located above the second voltage device region 101 with the wet etchant, the boundary morphology of the well region 1012 of the first-conductivity-type doped device region and the well region 1013 of the second-conductivity-type doped device region can be repaired.

As an example, the material of the sacrificial layer 2 is silicon dioxide, and the material of the shallow trench isolation structure 3 is silicon dioxide. In the process of removing the sacrificial layer 2 using the wet etchant, the amount of wet etchant needs to be considered to ensure that the sacrificial layer 2 is completely removed, and the amount of silicon dioxide loss of the shallow trench isolation structure also needs to be considered to control the remaining height of the shallow trench isolation structure 3, so as to avoid excessive loss of the shallow trench isolation structure 3 that would prevent it from achieving its isolation effect.

As an example, after removing the sacrificial layer 2 above the second voltage device region 101, the second voltage device region 101 is etched back using the hard mask layer 4 as a mask to form the trench 11 in the second voltage device region. After the etch-back of the second voltage device region 101 is completed, the hard mask layer 4 with a predetermined thickness remains on the semiconductor substrate 1 to avoid insufficient thickness of the hard mask layer 4 causing damage to the first voltage device region 100 and the third voltage device region 102.

Next, referring to FIG. 14, step S7 is performed: a gate dielectric layer 12 for the second voltage device region is formed in the trench 11 of the second voltage device region.

As an example, before forming the second voltage device region gate dielectric layer 12, the step of removing the remaining hard mask layer 4 is further included, that is, the remaining hard mask layer 4 is removed first, and then the gate dielectric layer 12 for the second voltage device region is formed.

As an example, the remaining hard mask layer 12 is removed by wet etching or dry etching; preferably, in this embodiment, the remaining hard mask layer 12 is removed by a wet etching method to reduce etching damage.

As an example, since the second voltage device region 101 is a medium- voltage device region and the third voltage device region 102 is a high-voltage device region, the thickness of the gate dielectric layer 12 for the second voltage device region is less than the thickness of the gate dielectric layer 1020 for the third voltage device region.

In summary, in the method for manufacturing the semiconductor device described in the present disclosure, a hard mask layer is formed before forming the well region of the first-conductivity-type doped device region and the well region of the second-conductivity-type doped device region, an opening of the hard mask layer is formed in the step of forming the well region of the first- conductivity-type doped device region and the well region of the second- conductivity-type doped device region, and then the hard mask layer serves as a barrier layer to etch the medium-voltage device region, eliminating the need for defining an active area recess etching in the medium-voltage device region, thereby reducing the number of mask layers required and lowering costs. Therefore, the present disclosure effectively overcomes various shortcomings in the existing technology and has high industrial utilization value.

The above-mentioned embodiments are merely illustrative of the principles and effects of the present disclosure, instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall still be covered by the claims of the present disclosure.

What is claimed is:

1. A method for manufacturing a semiconductor device, comprising:
S1: providing a semiconductor substrate, forming a sacrificial layer on an upper surface of the semiconductor substrate, wherein the semiconductor substrate is divided into a first voltage device region, a second voltage device region, and a third voltage device region, wherein the second voltage device region comprises a first-conductivity-type doped device region and a second-conductivity-type doped device region;
S2: forming a hard mask layer on the sacrificial layer, forming a first photoresist layer on the hard mask layer, patterning the first photoresist layer using a first photomask to form a first opening, wherein the first opening exposes the hard mask layer above the first-conductivity-type doped device region;
S3: etching the hard mask layer aligned to the patterned first photoresist layer to form a second opening, and performing ion implantation on the first-conductivity-type doped device region into the second opening to form a well region of the first-conductivity-type doped device region;
S4: forming a second photoresist layer on the hard mask layer and the seond opening in the hard mask layer, patterning the second photoresist layer using a second photomask to form a third opening, wherein the third opening exposes the hard mask layer above the second-conductivity-type doped device region;
S5: etching the hard mask layer aligned to the third hole in the patterned second photoresist layer to form a fourth opening in the hard mask layer, and performing ion implantation on the second-conductivity-type doped device region aligned to the third and the fourth openings to form a well region of the second-conductivity-type doped device region;
S6: etching to remove the secondphotoresist layer and the sacrificial layer above the second voltage device region using the second and fourth openings as a mask, and further etching the second voltage device region to a predetermined depth to form a trench in the second voltage device region; and
S7: forming a first gate dielectric layer for the second voltage device region in the trench of the second voltage device region.

2. The method for manufacturing the semiconductor device according to claim 1, wherein a material of the sacrificial layer comprises silicon oxide, and a material of the hard mask layer is silicon nitride.

3. The method for manufacturing the semiconductor device according to claim 1, wherein the sacrificial layer acts as an etching stop layer in a process of etching the hard mask layer to form the second opening; wherein the sacrificial layer acts as an etching stop layer in a process of etching the hard mask layer to form the fourth opening.

4. The method for manufacturing the semiconductor device according to claim 1, wherein in step S6, to remove the sacrificial layer above the second voltage device region comprises a wet etching technique.

5. The method for manufacturing the semiconductor device according to claim 4, wherein an etchant of the wet etching technique comprises an HF solution.

6. The method for manufacturing the semiconductor device according to claim 1, further comprising: forming a second gate dielectric layer for the third voltage device region in the third voltage device region before forming the hard mask layer.

7. The method for manufacturing the semiconductor device according to claim 6, wherein a thickness of the first gate dielectric layer for the second voltage device region is less than a thickness of the second gate dielectric layer for the third voltage device region.

8. The method for manufacturing the semiconductor device according to claim 1, wherein the first-conductivity-type doped device region is an N-type device region and the second-conductivity-type doped device region is a P-type device region; or the first-conductivity-type doped device region is a P-type device region and the second-conductivity-type doped device region is an N-type device region.

9. The method for manufacturing the semiconductor device according to claim 1, comprising: wherein in step S6, after forming the trench in the second voltage device region, the hard mask layer with the predetermined depth remains on the semiconductor substrate; wherein step S7 further comprises: first removing remaining hard mask layer from the upper surface of the substrate, and then forming the first gate dielectric layer for the second voltage device region.

10. The method for manufacturing the semiconductor device according to claim 9, wherein the remaining hard mask layer is removed by a wet etching method.
